(19) United States
(12) Patent Application Publication
(10) Pub. No.: US 2020/0227414 A1
(43) Pub. Date: Jul. 16, 2020

(54) SEMICONDUCTOR STRUCTURE AND METHOD FOR FORMING THE SAME

(71) Applicant: MACRONIX INTERNATIONAL CO., LTD., Hsinchu (TW)

(72) Inventors: Chao-Hung WANG, Tainan City (TW); Yu-Hsuan LIN, Taichung City (TW); Dai-Ying LEE, Hukou Township, Hsinchu County (TW)

(21) Appl. No.: 16/249,049

(22) Filed: Jan. 16, 2019

(51) Int. Cl. H01L 27/105

(52) U.S. Cl. CPC H01L 27/1052

(57) ABSTRACT

A semiconductor structure includes a memory array. The memory array has a plurality of memory units. The memory units include a first memory unit and a second memory unit. The first memory unit has a first resistance. The second memory unit has a second resistance. Both of the first resistance and the second resistance are in a range of 10⁵Ω to 10⁹Ω, and the second resistance is larger than the first resistance.

### TECHNICAL FIELD

This disclosure relates to a semiconductor structure and a method for forming the same. More particularly, this disclosure relates to a semiconductor structure comprising a memory array and a method for forming the same.

### BACKGROUND

Artificial intelligence (AI) has been developed for a long period, and attracts more attention recently. One type thereof is neural network. For a neural network architecture, precision of weight is one of the most important factors for getting high inference accuracy. As such, a robust memory is required for weight storage in computing-in-memory architecture. Such a robust memory is also beneficial for data/code storage in conventional computer.

Typically, the storage of a memory device is implemented by applying various voltages that write memory units to different states. However, such storage means may encounter problems like retention, instability, and the like.

### SUMMARY

This disclosure provides a semiconductor structure with a robust memory array and a method for forming the same.

According to some embodiments, a semiconductor structure comprises a memory array. The memory array comprises a plurality of memory units. The plurality of memory units includes a first memory unit and a second memory unit. The first memory unit has a first resistance. The second memory unit has a second resistance. Both of the first resistance and the second resistance are in a range of 10⁵Ω to 10⁹Ω, and the second resistance is larger than the first resistance.

According to some embodiments, a method for forming a semiconductor structure comprises forming an array of a plurality of memory units, wherein the plurality of memory units include a first memory unit and a second memory unit. Forming the array comprises following steps. First, an initial structure is provided, wherein the initial structure comprises a bottom electrode for the first memory unit and a bottom electrode for the second memory unit. Then, a resistive layer is optionally formed on the bottom electrode for the first memory unit, such that a first resistance of the first memory unit is in a range of 10⁵Ω to 10⁹Ω. A resistive layer is formed on the bottom electrode for the second memory unit, such that a second resistance of the second memory unit is in a range of 10⁵Ω to 10⁹Ω and larger than the first resistance.

### BRIEF DESCRIPTION OF THE DRAWINGS

FIGS. 1A-1C illustrate an exemplary arrangement for a semiconductor structure with single-level cells (SLCs).

FIG. 2 illustrates an exemplary memory unit.

FIGS. 3A-3C illustrate an exemplary arrangement for a semiconductor structure with multi-level cells (MLCs).

FIGS. 4A-4B to FIGS. 8A-8B illustrate an exemplary method for forming a semiconductor structure with SLCs.

FIGS. 9A-9B to FIGS. 13A-13B illustrate another exemplary method for forming a semiconductor structure with SLCs.

FIGS. 14A-14B to FIGS. 18A-18B illustrate still another exemplary method for forming a semiconductor structure with SLCs.

FIGS. 19A-19B to FIGS. 24A-24B illustrate a further exemplary method for forming a semiconductor structure with SLCs.

FIGS. 25A-25B to FIGS. 26A-26B illustrate still a further exemplary method for forming a semiconductor structure with SLCs.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation.

A semiconductor structure according to embodiments comprises a memory array. The memory array comprises a plurality of memory units. The plurality of memory units includes a first memory unit and a second memory unit. The first memory unit has a first resistance. The second memory unit has a second resistance. Both of the first resistance and the second resistance are in a range of 10⁵Ω to 10⁹Ω, and the second resistance is larger than the first resistance.

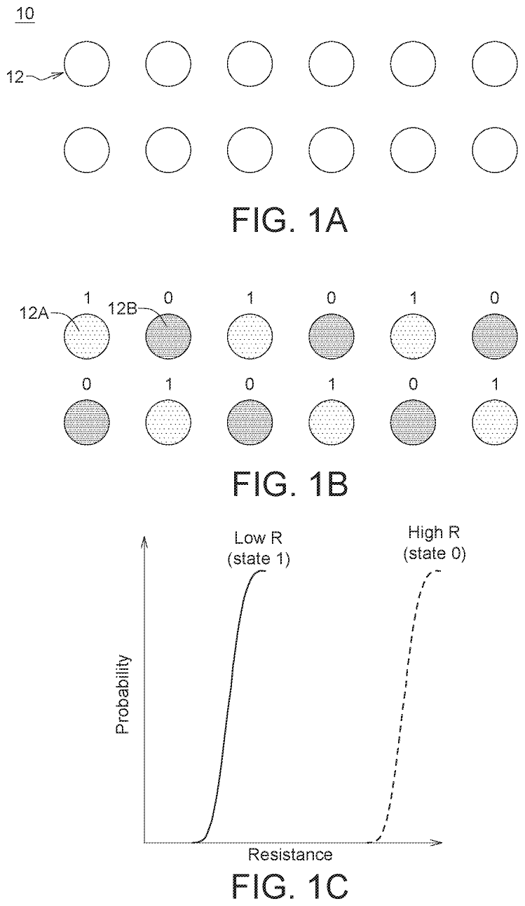

Referring to FIGS. 1A-1C, an exemplary arrangement for such a semiconductor structure is shown. In the case illustrated in FIGS. 1A-1C, the memory units are single-level cells (SLCs).

As shown in FIG. 1A, the semiconductor structure comprises a memory array 10. The memory array 10 comprises a plurality of memory units 12. Since the memory units 12 are SLCs, each of them may be set on a state “1” corresponding to a lower resistance or a state “0” corresponding to a higher resistance, as shown in FIG. 1B and FIG. 1C. Herein, a memory unit 12 being set on the state “1” is referred to as a first memory unit 12A, which has a first resistance, and a memory unit 12 being set on the state “0” is referred to as a second memory unit 12B, which has a second resistance. According to the embodiments, the first resistance and the second resistance are initial resistances of the first memory unit 12A and the second memory unit 12B respectively, which belong to an electrical property obtained from the material, manufacturing process, and design. In other words, the first resistance and the second resistance are not resistances obtained from an application of voltages after the structure is completely constructed. Such initial resistances are typically much higher than the resistances obtained from the application of voltages. According to some embodiments, the first resistance and the second resistance may be in a range of 10⁵Ω to 10⁹Ω. The second resistance is larger than the first resistance. In some embodiments, the second resistance is one to two orders of magnitude larger than the first resistance. For example, the second resistance may be 10 times to 100 times of the first resistance.

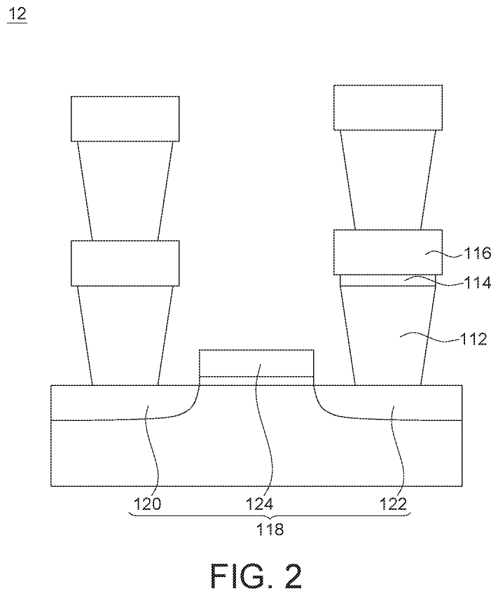

Now referring to FIG. 2, exemplary details of a memory unit 12 are shown. A memory unit 12 may comprise a bottom electrode, an optional resistive layer, a top electrode, and a control device, wherein the optional resistive layer is disposed on the bottom electrode, the top electrode is disposed on the optional resistive layer or disposed on the bottom electrode, and the control device is electrically coupled to the bottom electrode. The exemplary memory unit 12 shown in FIG. 2 comprises a conductive plug 112, such as a tungsten (W) plug, as the bottom electrode, a resistive layer 114, and a portion 116 of a metal layer as top electrode. The memory unit 12 shown in FIG. 2 is configured to be similar to a ReRAM structure, and a suitable ReRAM film may be used as the resistive layer 114. For example, a material of the optional resistive layer 114 comprises at least one selected from the group consisting of: oxide, nitride, oxynitride, resistive polysilicon, and silicide. In this exemplary memory unit 12, a transistor 118 is used as the control device. The transistor 118 comprises a source 120, a drain 122, and a gate 124, wherein the drain 122 is coupled to the conductive plug 112.

It is noted that other suitable configurations may be provided for the memory units 12. As an example, the resistive layer 114 may be disposed under the conductive plug 112 with the drain 122 as the bottom electrode and the conductive plug 112 as the top electrode. In another example, the resistive layer 114 may be disposed between two W plugs with one of which as the bottom electrode and the other one as the top electrode. In still some other examples, a via, a metal line, or a polysilicon structure may be used as one or two of the electrodes. The disclosure has no particular limitation to the configurations of the memory units 12 in practical applications.

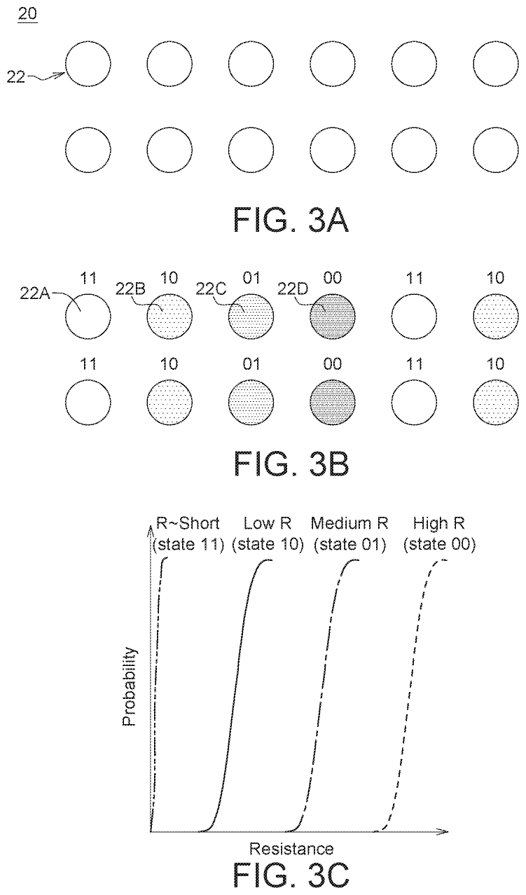

Referring to FIGS. 3A-3C, another exemplary arrangement for a semiconductor structure according to embodiments is shown. In the case illustrated in FIGS. 3A-3C, the memory units are multi-level cells (MLCs).

As shown in FIG. 3A, the semiconductor structure comprises a memory array 20. The memory array 20 comprises a plurality of memory units 22. Since the memory units 22 are MLCs, each of them may be set on a state “11” corresponding to a lowest resistance, a state “10” corresponding to a low resistance, a state “01” corresponding to a medium resistance, or a state “00” corresponding to a high resistance as shown in FIG. 3B and FIG. 3C. In some embodiments, the lowest resistance is implemented by directly connecting the top electrode to the bottom electrode without a resistive layer disposed therebetween, such that the top electrode and the bottom electrode are shorted. Herein, a memory unit 22 being set on the state “11” is referred to as a first memory unit 22A, which has a first resistance, a memory unit 22 being set on the state “10” is referred to as a second memory unit 22B, which has a second resistance, a memory unit 22 being set on the state “01” is referred to as a third memory unit 22C, which has a third resistance, a memory unit 22 being set on the state “00” is referred to as a fourth memory unit 22D, which has a fourth resistance. Similar to those described with respect to FIGS. 1A-1C, the first resistance, the second resistance, the third resistance, and the fourth resistance are initial resistance of the first memory unit 22A, the second memory unit 22B, the third memory unit 22C and the fourth memory unit 22D, respectively. As such, all of the first resistance, the second resistance, the third resistance, and the fourth resistance may be in the range of 10⁵Ω to 10⁹Ω. The second resistance is larger than the first resistance, the third resistance is larger than the second resistance, and the fourth resistance is larger than the third resistance. The resistances differences may be one to two orders of magnitude.

It is noted that the memory cells having more states, such as triple-level cells (TLCs), can be implemented in a similar manner.

A method for forming a semiconductor structure according to embodiments comprises forming an array of a plurality of memory units, wherein the plurality of memory units include a first memory unit and a second memory unit. Forming the array comprises following steps. First, an initial structure is provided, wherein the initial structure comprises a bottom electrode for the first memory unit and a bottom electrode for the second memory unit. Then, a resistive layer is optionally formed on the bottom electrode for the first memory unit, such that a first resistance of the first memory unit is in a range of 10⁵Ω to 10⁹Ω. A resistive layer is formed on the bottom electrode for the second memory unit, such that a second resistance of the second memory unit is in a range of 10⁵Ω to 10⁹Ω and larger than the first resistance.

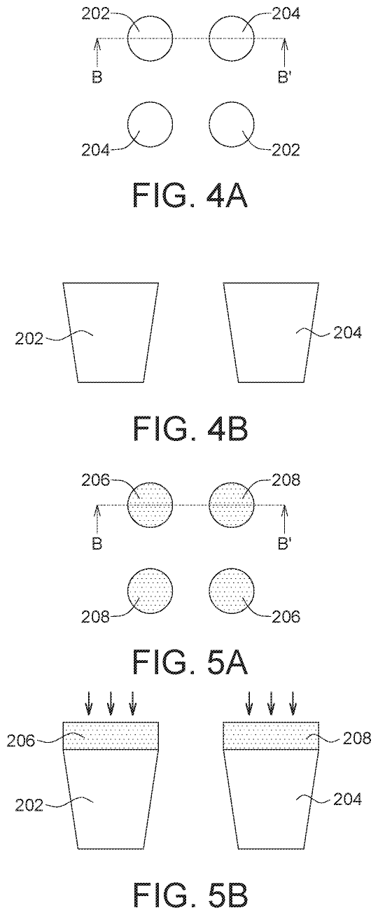

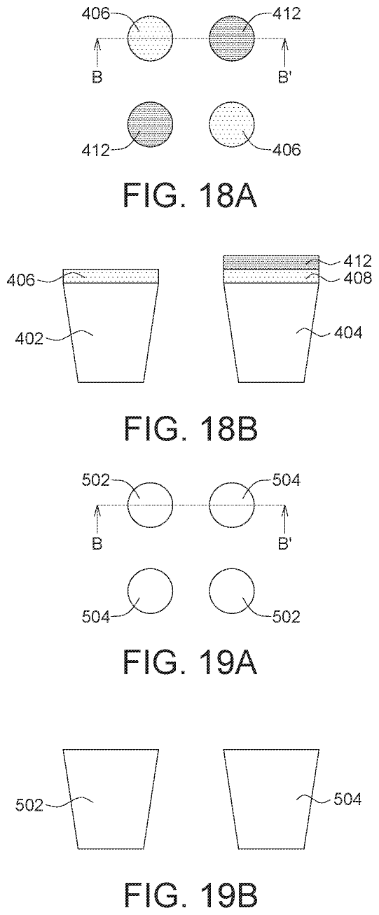

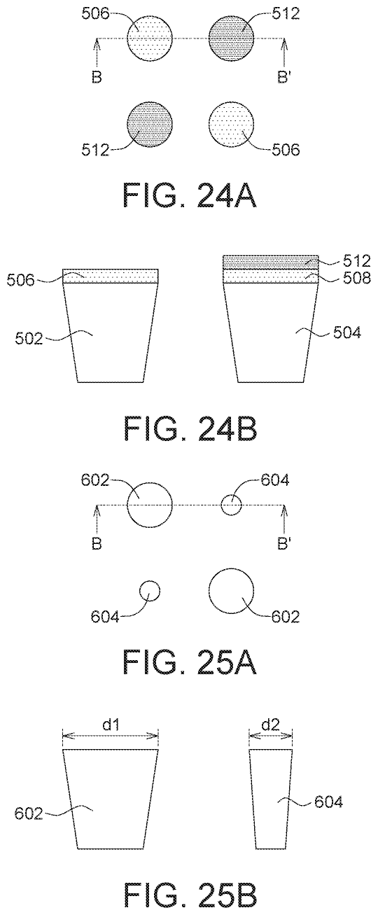

Now the examples of such a method are provided with reference to FIGS. 4A-4B to FIGS. 26A-26B, wherein the figures indicated by “A” are top views, and the figures indicated by “B” are cross sectional views along lines B-B′ in the figures indicated by “A”. For clarity, only the resistive layers and the corresponding bottom electrodes and masks are shown. In addition, in all of these examples, semiconductor structures with SLCs are illustrated. However, it is noted that semiconductor structures with memory cells having more states, such as MLCs and TLCs, can be implemented in a similar manner.

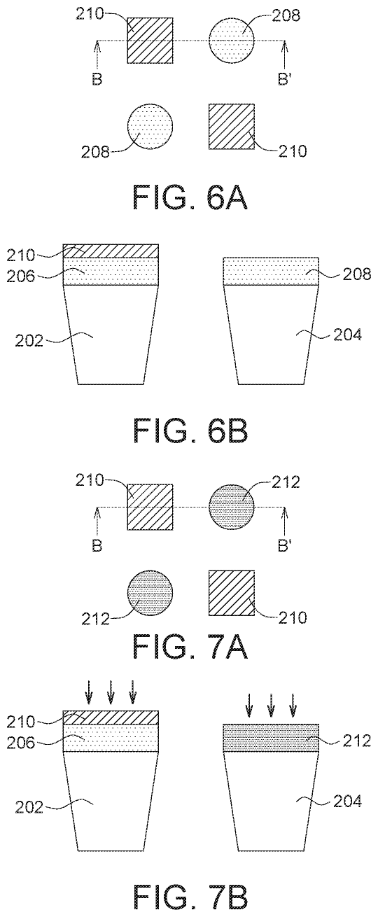

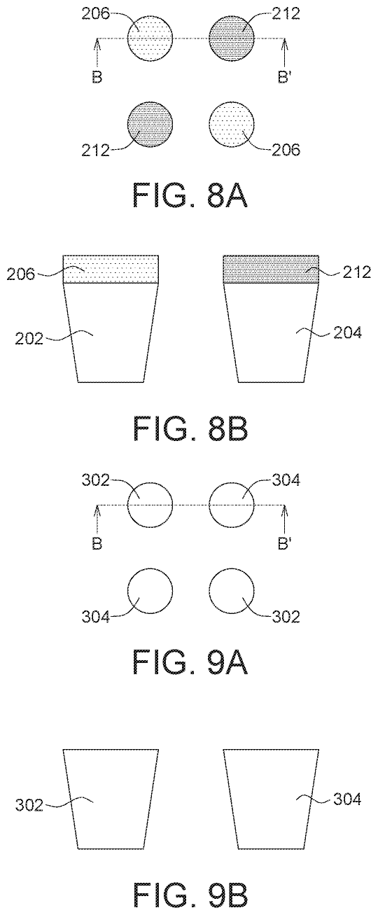

Referring to FIGS. 4A-4B to FIGS. 8A-8B, an exemplary method for forming a semiconductor structure with SLCs, particularly the steps for forming the array, is illustrated. First, the initial structure is provided, wherein the initial structure comprises a bottom electrode 202 for a first memory unit and a bottom electrode 204 for a second memory unit, as shown in FIGS. 4A-4B. Referring to FIGS. 5A-5B, the bottom electrode 202 for the first memory unit and the bottom electrode 204 for the second memory unit are oxidized, nitrided, or oxynitrided, as indicated by the arrows, such that a first resistive layer 206 is formed on the bottom electrode 202 for the first memory unit and another first resistive layer 208 is formed on the bottom electrode 204 for the second memory unit. Then, as shown in FIGS. 6A-6B, a mask 210 is provided on the first resistive layer 206 on the bottom electrode 202 for the first memory unit. The mask may be a photo resist, a hard mask, or any other suitable mask. Referring to FIGS. 7A-7B, the another first resistive layer 208 on the bottom electrode 204 for the second memory unit is further oxidized, nitrided, or oxynitrided, as indicated by the arrows, such that the another first resistive layer 208 is transferred into a second resistive layer 212. This oxidation, nitridation, or oxynitridaztion step is stronger than that in the step of FIGS. 5A-5B. This may be achieved by, for example, providing more reactants. Thereafter, as shown in FIGS. 8A-8B, the mask 210 on the first resistive layer 206 on the bottom electrode 202 for the first memory unit is removed.

As an example, according to some embodiments, the bottom electrode 202 and the bottom electrode 204 may be W plugs, the first resistive layer 206 and the first resistive layer 208 may be leaky WOₓ layers, and the second resistive layer 212 may be a dense WOₓ layer.

In the semiconductor structure formed thereby, a density of the resistive layer of the second memory unit (i.e., the second resistive layer 212) is larger than a density of the resistive layer of the first memory unit (i.e., the first resistive layer 206). In addition, due to the additional oxidation, nitridation, or oxynitridaztion step, a thickness of the resistive layer of the second memory unit (the second resistive layer 212) may be larger than a thickness of the resistive layer of the first memory unit (the first resistive layer 206).

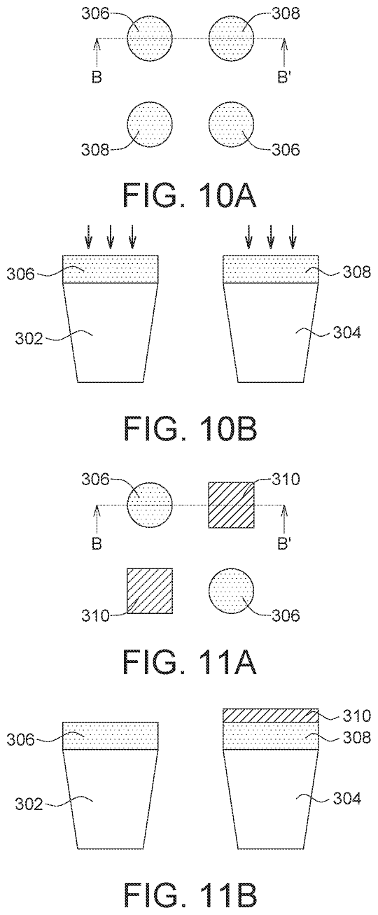

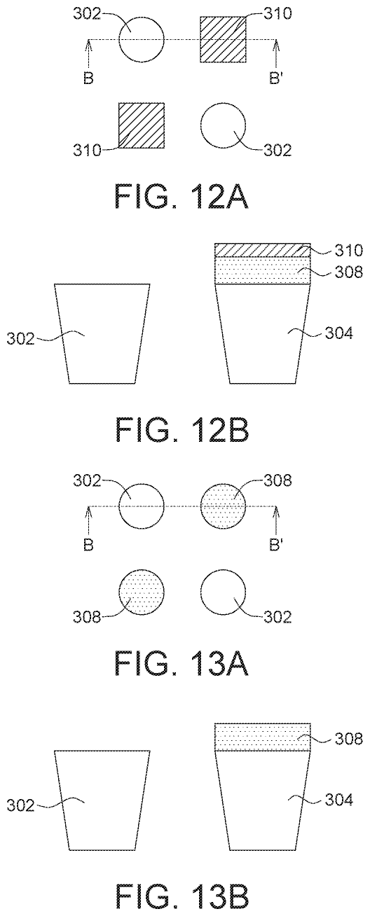

Referring to FIGS. 9A-9B to FIGS. 13A-13B, another exemplary method for forming a semiconductor structure with SLCs, particularly the steps for forming the array, is illustrated. First, the initial structure is provided, wherein the initial structure comprises a bottom electrode 302 for a first memory unit and a bottom electrode 304 for a second memory unit, as shown in FIGS. 9A-9B. Referring to FIGS. 10A-10B, the bottom electrode 302 for the first memory unit and the bottom electrode 304 for the second memory unit are oxidized, nitrided, or oxynitrided, as indicated by the arrows, such that a resistive layer 306 is formed on the bottom electrode 302 for the first memory unit and another resistive layer 308 is formed on the bottom electrode 304 for the second memory unit. Then, as shown in FIGS. 11A-11B, a mask 310 is provided on the another resistive layer 308 on the bottom electrode 304 for the second memory unit. Referring to FIGS. 12A-12B, the resistive layer 306 on the bottom electrode 302 for the first memory unit is removed. This step may be achieved by etching or any other suitable removing means. Thereafter, as shown in FIGS. 13A-13B, the mask 310 on the another resistive layer 308 on the bottom electrode 304 for the second memory unit is removed.

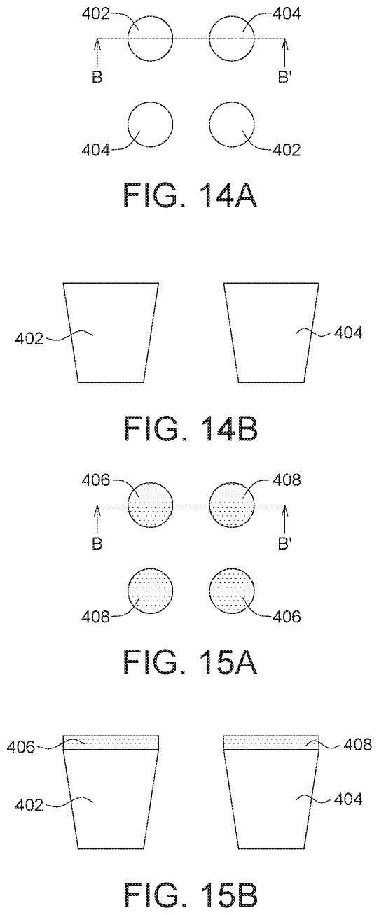

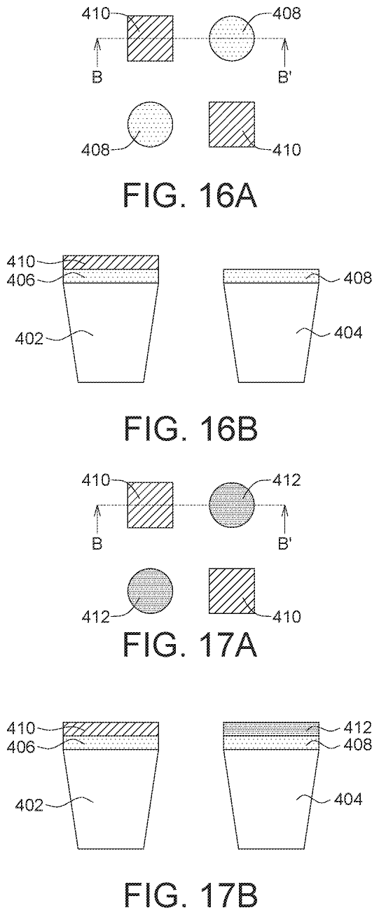

Referring to FIGS. 14A-14B to FIGS. 18A-18B, still another exemplary method for forming a semiconductor structure with SLCs, particularly the steps for forming the array, is illustrated. First, the initial structure is provided, wherein the initial structure comprises a bottom electrode 402 for a first memory unit and a bottom electrode 404 for a second memory unit, as shown in FIGS. 14A-14B. Referring to FIGS. 15A-15B, a first resistive sub-layer 406 is deposited on the bottom electrode 402 for the first memory unit and another first resistive sub-layer 408 is deposited on the bottom electrode 404 for the second memory unit. Then, as shown in FIGS. 16A-16B, a mask 410 is provided on the first resistive sub-layer 406 on the bottom electrode 402 for the first memory unit. Referring to FIGS. 15A-15B, a second resistive sub-layer 412 is deposited on the another first resistive sub-layer 408 on the bottom electrode 404 for the second memory unit. Thereafter, the mask 410 on the first resistive sub-layer 406 on the bottom electrode 402 for the first memory unit is removed.

In the semiconductor structure formed thereby, the first resistive sub-layer 406 constitute the resistive layer of the first memory unit, and first resistive sub-layer 408 and the second resistive sub-layer 412 together constitute the resistive layer of the second memory unit. As such, a total number of resistive sub-layers of the resistive layer of the second memory unit is larger than a total number of one or more resistive sub-layers of the resistive layer of the first memory unit. In addition, a thickness of the resistive layer of the second memory unit is larger than a thickness of the resistive layer of the first memory unit.

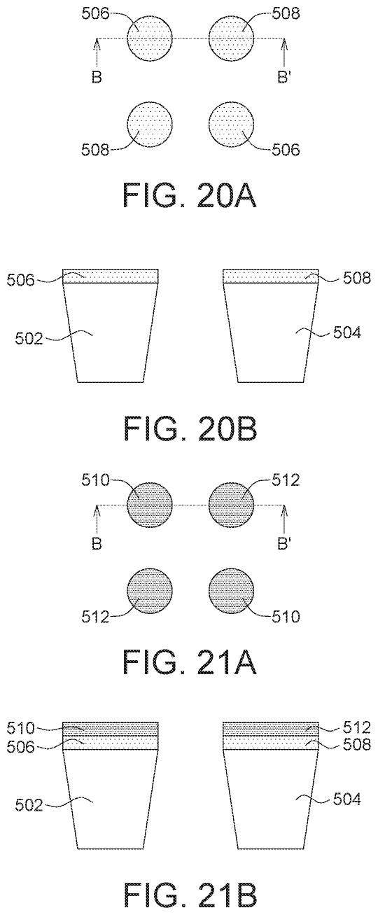

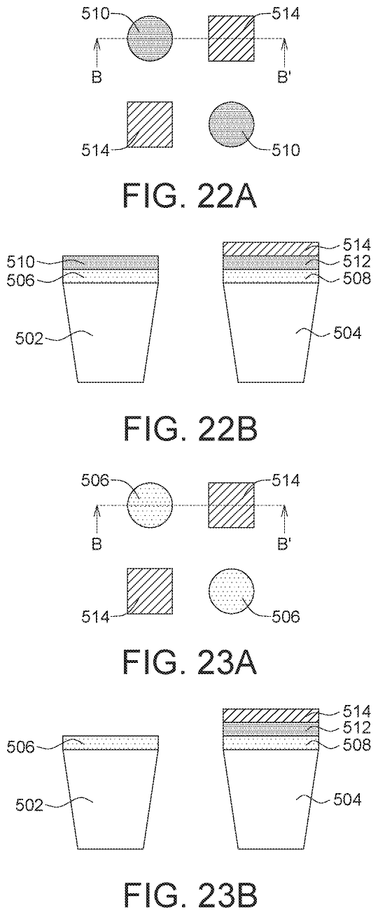

Referring to FIGS. 19A-19B to FIGS. 24A-24B, a further exemplary method for forming a semiconductor structure with SLCs, particularly the steps for forming the array, is illustrated. First, the initial structure is provided, wherein the initial structure comprises a bottom electrode 502 for a first memory unit and a bottom electrode 504 for a second memory unit, as shown in FIGS. 19A-19B. Referring to FIGS. 20A-20B, a first resistive sub-layer 506 is deposited on the bottom electrode 502 for the first memory unit and another first resistive sub-layer 508 is deposited on the bottom electrode 504 for the second memory unit. Referring to FIGS. 21A-21B, a second resistive sub-layer 510 is deposited on the first resistive sub-layer 506 on the bottom electrode 502 for the first memory unit and another second resistive sub-layer 512 is deposited on the another first resistive sub-layer 508 on the bottom electrode 504 for the second memory unit. Then, as shown in FIGS. 22A-22B, a mask 514 is provided on the another second resistive sub-layer 512 on the another first resistive sub-layer 508 on the bottom electrode 504 for the second memory unit. Referring to FIGS. 23A-23B, the second resistive sub-layer 510 on the first resistive sub-layer 506 on the bottom electrode 502 for the first memory unit is removed. Thereafter, the mask 514 on the another second resistive sub-layer 512 on the another first resistive sub-layer 508 on the bottom electrode 504 for the second memory unit is removed.

Similarly, in the semiconductor structure formed thereby, the first resistive sub-layer 506 constitute the resistive layer of the first memory unit, and first resistive sub-layer 508 and the second resistive sub-layer 512 together constitute the resistive layer of the second memory unit. As such, a total number of resistive sub-layers of the resistive layer of the second memory unit is larger than a total number of one or more resistive sub-layers of the resistive layer of the first memory unit. In addition, a thickness of the resistive layer of the second memory unit is larger than a thickness of the resistive layer of the first memory unit.

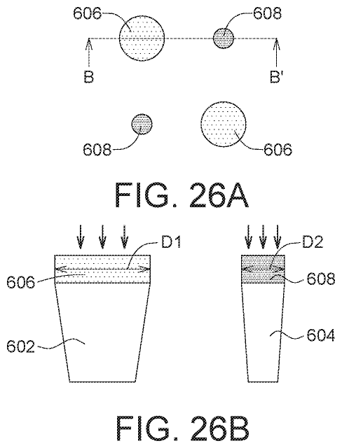

Referring to FIGS. 25A-25B to FIGS. 26A-26B, still a further exemplary method for forming a semiconductor structure with SLCs, particularly the steps for forming the array, is illustrated. First, the initial structure is provided, wherein the initial structure comprises a bottom electrode 602 for a first memory unit and a bottom electrode 604 for a second memory unit, and a diameter d2 of the bottom electrode 604 for the second memory unit is smaller than a diameter d1 of the bottom electrode 602 for the first memory unit (d2<d1), as shown in FIGS. 25A-25B. According to some embodiments, the diameter d2 of the bottom electrode 604 for the second memory unit is at least three times smaller than the diameter d1 of the bottom electrode 602 for the first memory unit. Referring to FIGS. 26A-26B, the bottom electrode 602 for the first memory unit and the bottom electrode 604 for the second memory unit is oxidized, nitrided, or oxynitrided, such that a resistive layer 606 is formed on the bottom electrode 602 for the first memory unit and another resistive layer 608 is formed on the bottom electrode 604 for the second memory unit. Due to the different diameters of the bottom electrode 602 and the bottom electrode 604, the densities of the formed resistive layer 606 and the resistive layer 608 will be different. For example, the resistive layer 606 formed on the larger bottom electrode 602 may be a leaky WOₓ layer, and the resistive layer 608 formed on the smaller bottom electrode 604 may be a dense WOₓ layer.

In the semiconductor structure formed thereby, a diameter D2 of the resistive layer 608 of the second memory unit is smaller than a diameter D1 of the resistive layer 606 of the first memory unit. The diameter D2 of the resistive layer 608 of the second memory unit may be at least three times smaller than the diameter D1 of the resistive layer 606 of the first memory unit. For example, the diameter D2 of the resistive layer 608 of the second memory unit may be lower than 0.1 μm, and the diameter D1 of the resistive layer 606 of the first memory unit may be larger than 0.3 μm. A density of the resistive layer 608 of the second memory unit is larger than a density of the resistive layer 606 of the first memory unit.

It is noted that the forming methods as described above is compatible with typical manufacturing processes for semiconductor structures. For example, each memory unit may have the configuration as shown in FIG. 2. In such a case, the initial structure may comprise a plurality of control devices (118) and a plurality of bottom electrodes (112) electrically coupled to the control devices, respectively for a plurality of memory units. In addition, the formation of the array may comprise forming resistive layers 114 on a portion of the bottom electrodes (112), respectively according to any embodiment as described above. Then, top electrodes (116) may be formed on the resistive layers 114 and on another portion of the bottom electrodes (112) on which no resistive layer 114 is formed.

In addition, as described above, the forming methods according to the embodiments may be suitable for forming a semiconductor structure with memory cells having more states, such as MLCs and TLCs. In such a case, the plurality of memory units further includes a third memory unit and a fourth memory unit. The formation of the array comprise providing an initial structure further comprising a bottom electrode for the third memory unit and a bottom electrode for the fourth memory unit. A resistive layer is formed on the bottom electrode for the third memory unit, such that a third resistance of the third memory unit is in a range of 10⁵Ω to 10⁹Ω and larger than the second resistance. In addition, a resistive layer is formed on the bottom electrode for the fourth memory unit, such that a fourth resistance of the fourth memory unit is in a range of 10⁵Ω to 10⁹Ω and larger than the third resistance.

In summary, in this disclosure, initial resistances are used to set the states of memory units. In other words, the code implementation can be conducted through controlling the resistance level of the memory units during the formation thereof. Since an initial resistance is the most stable resistance state for a memory cell and can be easily adjusted by manufacturing design, a robust memory can be provided. It is particularly suitable for AI, but is not limited thereto. It is contemplated that the design may be combined with other types of code implementation, such as adjusting the threshold voltages, capacitances, p-n MOSFET mismatch, etc. performed during the manufacturing process.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a memory array comprising a plurality of memory units, the plurality of memory units including:
a first memory unit having a first resistance; and
a second memory unit having a second resistance;
wherein both of the first resistance and the second resistance are in a range of 10⁵Ω to 10⁹Ω, and the second resistance is larger than the first resistance.

2. The semiconductor structure according to claim 1, wherein each of the memory units comprises:
a bottom electrode;
an optional resistive layer disposed on the bottom electrode;
a top electrode disposed on the optional resistive layer or disposed on the bottom electrode; and
a control device electrically coupled to the bottom electrode.

3. The semiconductor structure according to claim 2, wherein a material of the optional resistive layer comprises at least one selected from the group consisting of: oxide, nitride, oxynitride, resistive polysilicon, and silicide.

4. The semiconductor structure according to claim 1, wherein a density of a resistive layer of the second memory unit is larger than a density of a resistive layer of the first memory unit.

5. The semiconductor structure according to claim 1, wherein a total number of resistive sub-layers of a resistive layer of the second memory unit is larger than a total number of one or more resistive sub-layers of a resistive layer of the first memory unit.

6. The semiconductor structure according to claim 1, wherein a thickness of a resistive layer of the second memory unit is larger than a thickness of a resistive layer of the first memory unit.

7. The semiconductor structure according to claim 1, wherein a diameter of a resistive layer of the second memory unit is smaller than a diameter of a resistive layer of the first memory unit.

8. The semiconductor structure according to claim 7, wherein the diameter of the resistive layer of the second memory unit is at least three times smaller than the diameter of the resistive layer of the first memory unit.

9. The semiconductor structure according to claim 1, wherein the plurality of memory units further including:
a third memory unit having a third resistance; and
a fourth memory unit having a fourth resistance;
wherein all of the first resistance, the second resistance, the third resistance, and the fourth resistance are in the range of 10⁵Ω to 10⁹Ω, the second resistance is larger than the first resistance, the third resistance is larger than the second resistance, and the fourth resistance is larger than the third resistance.

10. The semiconductor structure according to claim 1, wherein the second resistance is one to two orders of magnitude larger than the first resistance.

11. A method for forming a semiconductor structure, comprising:
forming an array of a plurality of memory units, wherein the plurality of memory units include a first memory unit and a second memory unit, and forming the array comprises:
providing an initial structure, wherein the initial structure comprises a bottom electrode for the first memory unit and a bottom electrode for the second memory unit;
optionally forming a resistive layer on the bottom electrode for the first memory unit, such that a first resistance of the first memory unit is in a range of 10⁵Ω to 10⁹Ω; and
forming a resistive layer on the bottom electrode for the second memory unit, such that a second resistance of the second memory unit is in a range of 10⁵Ω to 10⁹Ω and larger than the first resistance.

12. The method according to claim 11, wherein forming the array comprises:
oxidizing, nitriding, or oxynitriding the bottom electrode for the first memory unit and the bottom electrode for the second memory unit, such that a first resistive layer is formed on the bottom electrode for the first memory unit and another first resistive layer is formed on the bottom electrode for the second memory unit;
providing a mask on the first resistive layer on the bottom electrode for the first memory unit;
further oxidizing, nitriding, or oxynitriding the another first resistive layer on the bottom electrode for the second memory unit, such that the another first resistive layer is transferred into a second resistive layer; and
removing the mask on the first resistive layer on the bottom electrode for the first memory unit.

13. The method according to claim 11, wherein forming the array comprises:
oxidizing, nitriding, or oxynitriding the bottom electrode for the first memory unit and the bottom electrode for the second memory unit, such that an resistive layer is formed on the bottom electrode for the first memory unit and another resistive layer is formed on the bottom electrode for the second memory unit;
providing a mask on the another resistive layer on the bottom electrode for the second memory unit;
removing the resistive layer on the bottom electrode for the first memory unit; and
removing the mask on the another resistive layer on the bottom electrode for the second memory unit.

14. The method according to claim 11, wherein forming the array comprises:
depositing a first resistive sub-layer on the bottom electrode for the first memory unit and depositing another first resistive sub-layer on the bottom electrode for the second memory unit;
providing a mask on the first resistive sub-layer on the bottom electrode for the first memory unit;
depositing a second resistive sub-layer on the another first resistive sub-layer on the bottom electrode for the second memory unit; and
removing the mask on the first resistive sub-layer on the bottom electrode for the first memory unit.

15. The method according to claim 11, wherein forming the array comprises:
depositing a first resistive sub-layer on the bottom electrode for the first memory unit and depositing another first resistive sub-layer on the bottom electrode for the second memory unit;
depositing a second resistive sub-layer on the first resistive sub-layer on the bottom electrode for the first memory unit and depositing another second resistive sub-layer on the another first resistive sub-layer on the bottom electrode for the second memory unit;
providing a mask on the another second resistive sub-layer on the another first resistive sub-layer on the bottom electrode for the second memory unit;
removing the second resistive sub-layer on the first resistive sub-layer on the bottom electrode for the first memory unit; and
removing the mask on the another second resistive sub-layer on the another first resistive sub-layer on the bottom electrode for the second memory unit.

16. The method according to claim 11, wherein forming the array comprises:
providing the initial structure, wherein a diameter of the bottom electrode for the second memory unit is smaller than a diameter of the bottom electrode for the first memory unit; and
oxidizing, nitriding, or oxynitriding the bottom electrode for the first memory unit and the bottom electrode for the second memory unit, such that a resistive layer is formed on the bottom electrode for the first memory unit and another resistive layer is formed on the bottom electrode for the second memory unit.

17. The method according to claim 16, wherein the diameter of the bottom electrode for the second memory unit is at least three times smaller than the diameter of the bottom electrode for the first memory unit.

18. The method according to claim 11, wherein the initial structure comprises a plurality of control devices and a plurality of bottom electrodes electrically coupled to the control devices, respectively for a plurality of memory units.

19. The method according to claim 18, wherein forming the array comprises:
forming resistive layers on a portion of the bottom electrodes, respectively; and
forming top electrodes on the resistive layers or on another portion of the bottom electrodes on which no resistive layer is formed.

20. The method according to claim 11, wherein the plurality of memory units further includes a third memory unit and a fourth memory unit, and forming the array comprises:
providing the initial structure, wherein the initial structure further comprises a bottom electrode for the third memory unit and a bottom electrode for the fourth memory unit;
forming a resistive layer on the bottom electrode for the third memory unit, such that a third resistance of the third memory unit is in a range of 10⁵Ω to 10⁹Ω and larger than the second resistance; and
forming a resistive layer on the bottom electrode for the fourth memory unit, such that a fourth resistance of the fourth memory unit is in a range of 10⁵Ω to 10⁹Ω and larger than the third resistance.
